(19) United States
(12) Patent Application Publication
(10) Pub. No.: US 2010/0098966 A1
(43) Pub. Date: Apr. 22, 2010

(54) Process for preparing nanogap electrode and nanogap device using the same

(76) Inventors: Chil Seong Ah, Daejeon (KR); Yong Ju Yun, Daejeon (KR); Jun Sung Lee, Daejeon (KR); Hyung Ju Park, Pusan (KR); Dong Han Ha, Daejeon (KR); Wan Soo Yun, Daejeon (KR)

Correspondence Address: CLARK & BRODY, 1090 VERMONT AVENUE, NW, SUITE 250, WASHINGTON, DC, 20005, US

(21) Appl. No.: 11/991,071

(22) PCT Filed: Aug. 3, 2006
(86) PCT No.: PCT/KR2006/003053

§ 371 Date: Feb. 27, 2008

(30) Foreign Application Priority Data
May 2, 2006 (KR) 10-2006-0039528

(51) Int. Cl. B32B 3/00; B05D 5/12; G03F 7/20

(52) U.S. Cl. 428/600; 427/124; 427/126.1; 430/296; 430/311; 977/810; 977/890

(57) ABSTRACT

The present invention relates to a process of preparing a nanogap electrode and a nanogap device using the same, and a preparing process according to the present invention is characterized in that reduced metal is grown by reduction reaction from a metal ion in solution on the surface of a metal pattern with a predetermined shape. A method of preparing a nanogap electrode according to the present invention has an advantage that nanogap electrodes having a gap distance of 1-100 nm, which are difficult to prepare by a conventional method, can be easily prepared in a reproducible and uniform manner.

### TECHNICAL FIELD

The present invention relates to a process of preparing a nanogap metal electrode and a nanogap device using the same, and a preparing process according to the present invention is characterized in that reduced metal is grown by reduction reaction from a metal ion in solution on the surface of a metal pattern formed with a predetermined shape.

### BACKGROUND ART

The present invention relates to a process of forming an electrode having a nanogap. A nanogap electrode means an electrode having a gap distance of about 1-100 nm. As a process of preparing a nanogap electrode comes out in recent years, new technology has been developed at a fast speed in the field of measuring and applying the characteristics of nano-tube, nano-particle, nano-wire, or the like as well as materials having the size of nanometer scale, such as protein and DNA.

However, it is very difficult to prepare the nanogap of 100 nm or less due to the restriction of its process when the conventional semiconductor process technologies are used.

In recent years, there has been proposed a method of forming a nanogap or angstrom (Å) gap by means of mechanical break junction (C. Zhou, C. J. Muller, M. R. Deshpande, J. W. Sleight, and M. A. Reed, Appl. Phys. Lett. 67, 1160 (1995); R. Reichert, R. Ochs, D. Beckmann, H. B. Weber, M. Mayor, and H. v. Lohneysen, Phys. Rev. Lett. 88, 176804-1 (2002)), electromigration (H. Park, A. K. L. Lim, A. P. Alivisatos, J. Park, and P. L. McEuen, Appl. Phys. Lett. 75, 301 (1999)) and the like, but these methods are only useful for a method of forming a very narrow gap of about 1 nm, but difficult to prepare a nanogap having the range of 3-100 nm. Moreover, these methods are not easy to be commercialized due to its low reproducibility, and it is impossible to prepare an arbitrary-shaped nanogap or multiple nanogaps.

On the other hand, a method of forming a nanogap electrode on a semiconductor substrate by wet-etching of a mesa structure is publicly known (R. Krahne, A. Yacoby, H. Shtrikman, I. Bar-Joseph, T. Dadosh, and J. Sperling, Appl. Phys. Lett. 81, 730 (2002)), but it also cannot be an economical and reproducible method for preparing a nanogap electrode having an arbitrary shape or multiple nanogap electrodes, which are separated by several nanometers.

Besides, there is a method of electrodeposition (C. Z. Li, H. X. He, and N. J. Tao, Appl. Phys. Lett. 77, 3995 (2000); A. F. Morpurgo, C. M. Marcus, and D. B. Robinson, Appl. Phys. Lett. 74, 2084 (1999)) or the like, but this method is also complicated in its preparing process, and has a disadvantage that a nanogap electrode having an arbitrary shape or multiple nanogap electrodes cannot be prepared in the same manner as break junction technology or the like.

### DISCLOSURE

### Technical Problem

The present invention is devised in order to solve the above-mentioned problems, and an object of the present invention is to provide a method of preparing a reproducible nanogap electrode, and another object of the invention is to provide a method of preparing a nanogap electrode having an arbitrary shape or multiple nanogap electrodes, as well as to provide an economical method of preparing a nanogap electrode which can be used in the field of biosensor or the like, furthermore, to provide a device using a nanogap electrode which is prepared through this method.

### Technical Solution

The present invention relates to a process of preparing a nanogap electrode and a nanogap device using the same. A preparing process according to the present invention is characterized in that reduced metal is grown by reduction reaction from a metal ion in solution on the surface of a metal pattern formed with a predetermined shape. The method of growing metal on the surface of a metal pattern is surface-catalyzed chemical deposition. According to the present invention, interdigitated nanogap electrodes having a gap distance of 1-100 nm can be prepared with high yield (greater than 90%) and reproducibility. A nanogap electrode of about 10 nm can be prepared, which is particularly difficult to be prepared.

A method of preparing a nanogap electrode is specifically characterized in that a substrate formed with a metal pattern having a predetermined shape is immersed in a solution containing a metal ion, and then reduced metal is grown from the metal ion in solution on the surface of a metal pattern by adding a reducing agent. Furthermore, metal can be grown by repeating a step of immersing a substrate with a metal pattern in several reaction baths filled with a solution containing a metal ion and a reducing agent, where the concentration of metal ion can be same for reaction baths, or the metal ion solution having a different concentration can be used.

A method of preparing a nanogap electrode according to the present invention will be described with reference to FIG. 1. Using a metal pattern 2 formed with a predetermined shape, a metal growth layer 3 is formed by the reduction reaction of a metal ion on the metal pattern 2. The gap of the metal pattern 2 is not particularly restricted but it is appropriate to have a gap of about 50-500 nm, and the metal pattern 2 can be formed on a substrate 1 by a typical method selected from electron beam lithography, photo lithography, X-ray lithography, printing method, and the like, and the metal may be Au, Ag, Al, Cu, or Pt.

The metal pattern may further include a metal adhesive layer which is selected from Ti, Ni, Cr, or the like, between the substrate and the metal pattern to increase the adhesion to the substrate.

For the metal ion, considering the common use with the metal pattern, it is preferable to use an ion which is resulted from the same metal as the metal pattern, but it may be also possible to use a different metal ion, and in fact any metal ion can be employed if it has conductivity through reduction. The metal ion is exemplified by HAuCl₄, AgNO₃, AuCl, AuCl₂, AuCl₃, AuCl₄, Au(CO)Cl, NaAuCl₄, and CuSO₄, and water or a mixed solvent of water and an organic solvent can be used as a solvent for dissolving the metal ion, and it is preferable to have low concentration of about 1 μM-1 mM.

On the other hand, a substrate formed with a metal pattern is immersed in a solution containing the metal ion, and then the metal ion in the solution is reduced by a reducing agent, thereby being deposited and grown on the metal pattern to form a nanogap. For the reducing agent, it is preferable to use a weak reducing agent for appropriately controlling the reduction rate of metal ions, including Lewis acid or weak Bronsted acid, and especially it can be exemplified by hydroxylamine (H₂NOH), ascorbic acid, glucose, Rochelle salt, formaldehyde.

The method of preparing a nanogap electrode according to the present invention is characterized in that the condition of weak reducing agent and low metal ion concentration is employed, thereby removing the possibility of nucleation in solution and metal being grown selectively only on the surface of a metal pattern where the surface energy is high.

The reaction formula occurring on the surface of a metal pattern is shown as follows, for example, in case of hydroxylamine (H₂NOH).

H₃NOH⁺ [symbol] H₃NOH_{ads}⁺⁻,

H₃NOH_{ads}⁺ [symbol] H₂NO_{ads}+2H⁺+e⁻

H₂NO_{ads}→HNO_{ads}+H⁺+e⁻

HNO_{ads} [symbol] NO_{ads}+H⁺+e⁻

AuCl₄⁻+3e⁻ [symbol] Au⁰+4Cl⁻

A reducing agent H₂NOH is protonated, and then absorbed (”ads” means an absorbed state on the metal surface) to be oxidized to NO on the surface of a metal pattern, and metal ions are deposited onto the metal pattern by reduction reaction on the location where the NO is absorbed.

In the process of forming a nanogap according to the present invention, a growth rate distribution is illustrated by arrows in FIG. 1. As metal growth is progressed, the mass transfer is hindered in the gap region between the metal electrodes, thereby the reaction speed (growth rate) being gradually slowed down. The gap distance of a nanogap electrode can be controlled by the concentration of metal ions and reducing agent and their reaction time, and it will become narrow as the reaction time and concentration increase.

### DESCRIPTION OF DRAWINGS

The above and other objects, features and advantages of the present invention will become apparent from the following description of preferred embodiments given in conjunction with the accompanying drawings, in which:

FIG. 1 is a schematic diagram illustrating a process of preparing a nanogap electrode;

FIG. 2 is a FESEM photograph (a) of a gold pattern formed by an electron beam lithography method, and a FESEM photograph (b) of a nanogap gold electrode formed on the surface of the gold pattern;

FIG. 3 is an I-V graph of a nanogap electrode as illustrated in FIG. 2(b);

FIG. 4 is a FESEM photograph of a nanogap electrode formed with a three-pole electrode according to the present invention;

FIG. 5 is a FESEM photograph of an interdigitated gold electrode;

FIG. 6 is a FESEM photograph of an interdigitated nanogap gold electrode formed on the surface of the interdigitated gold electrode as illustrated in FIG. 5;

FIG. 7 is a FESEM photograph of 20,000 nanogap electrodes; and

FIG. 8 is a FESEM photograph (a) of 40×10 nanogap electrodes, and a histogram (b) of the gap distance of the nanogap electrodes.

### DETAILED DESCRIPTION OF MAIN ELEMENTS

1: substrate, 2: metal pattern, 3: metal growth layer

### Best Mode

Hereinafter, the embodiments of the present invention will be described in detail with reference to accompanying drawings. A method of preparing a nanogap electrode according to the present invention will be described through the embodiments, but those embodiments should not be construed to restrict the scope of the invention.

### Embodiment 1

An electron resist (ER) was coated on a SiOx substrate to form an electron resist pattern using an electron beam lithography process, and then 10 nm Ti was deposited as a metal adhesive layer and 50 nm Au was then deposited, and then a Ti/Au (10 nm/50 nm) having a gap distance of about 40 nm was made using a typical electron beam lithography process for lifting off the electron resist. Subsequently, it was dipped in a piranha solution (H₂SO₄/30% H₂O₂=5:1(v/v)) at 50° C. for 10 minutes, and then washed with pure water several times and then dried in nitrogen atmosphere.

1 mL of 400 μM HAuCl₄ aqueous solution was added to 10 mL of water in which a substrate formed with the gold pattern is immersed, and then 1 mL of 640 μM NH₂OH aqueous solution was added, and then reacted at 27.5° C. for 2 minutes, and this process was repeated four times.

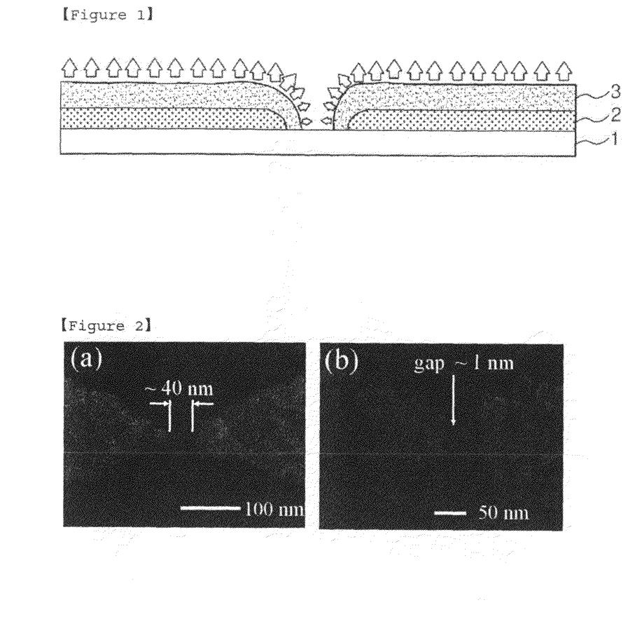

FIG. 2 is a FESEM photograph (a) showing a gold pattern formed by an electron beam lithography, and a FESEM photograph (b) showing a nanogap gold electrode formed on the surface of the gold pattern. When the FESEM photograph of a gold pattern of FIG. 2(a) prior to metal growth is compared with the FESEM photograph (b) of a nanogap gold electrode formed on the surface of the gold pattern according to the embodiment 1 of FIG. 2(a), it is confirmed that the gap distance of about 40 nm prior to gold growth became narrowed to about 1 nm.

### [Experimental Example] Measurement of a Nanogap

Based on an equation expressed in a paper written by P. Steinmann et al. (J. Vac. Sci. Technol. B 22, 3178(2004)) and a measured value of the nanogap electrode prepared by the embodiment 1, it is confirmed that the nanogap distance was 1 nm.

In case where the gap of a pattern becomes very narrow to 2 nm or less as shown in FIG. 2(b), it may be difficult to measure a nanogap using SEM. Then, the gap distance can be estimated using an electrical measurement value and a mathematical calculation, which is expressed as Equation 1.

$$I = \frac{{k}_{1} A}{{s}^{2}} [ {X}^{2} exp ( - {k}_{2} sX ) - {Y}^{2} exp ( - {k}_{2} sY ) ] \\ X = \sqrt{φ - V / 2} , \\ Y = \sqrt{φ + V / 2} , \\ {k}_{1} = 6.32 \times {10}^{10} {Vs}^{- 1} , \\ {k}_{2} = 1.025 {J}^{- 1 / 2} \qquad [ Equation 1 ]$$

A: emission area (cm²), s: electrode separation (Å), φ: barrier height (eV)

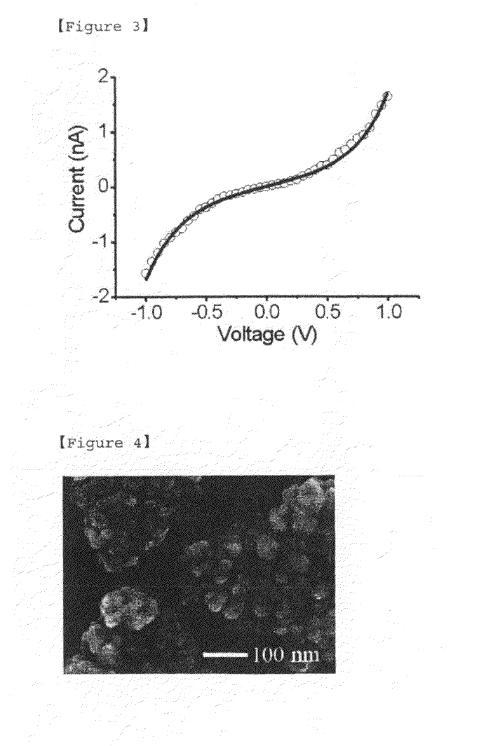

An I-V curve expressed by a solid line in FIG. 3 is obtained by a least-square method for the measured values, and the I-V curve is obtained with s=1.0 nm, φ=0.8 eV, and A=3.0×10⁻¹⁵ cm² in the Equation 1. This matches well with a paper written by Hahn et al. (Appl. Phys, A:Mater. Sci. Process. 66, S467(1998)) where the φ value (barrier height) is described to be about 0.8 eV. As a result, it is confirmed that the nanogap distance of a nanogap electrode of the embodiment 1 was 1 nm.

### Embodiment 2

Except for forming a Ti/Au pattern into three-poles on a SiOx substrate, this was similarly progressed as described in embodiment 1, and in FIG. 4 it is illustrated a FESEM photograph of a nanogap electrode with three-poles.

### Embodiment 3

An interdigitated gold pattern having a gap of about 100 nm and a length of 15 μm on a SiOx substrate was similarly made by an electron beam lithography process as described in embodiment 1, and then a process was repeated four times, wherein a substrate formed with the gold pattern was placed into 11 mL of 36 μM concentrated HAuCl₄ aqueous solution, and 1 mL of 640 μM NH₂OH aqueous solution was added, and then reacted at 27° C. for 2 minutes, thereby allowing gold to be grown on the surface of the interdigitated gold pattern to prepare interdigitated nanogap gold electrodes.

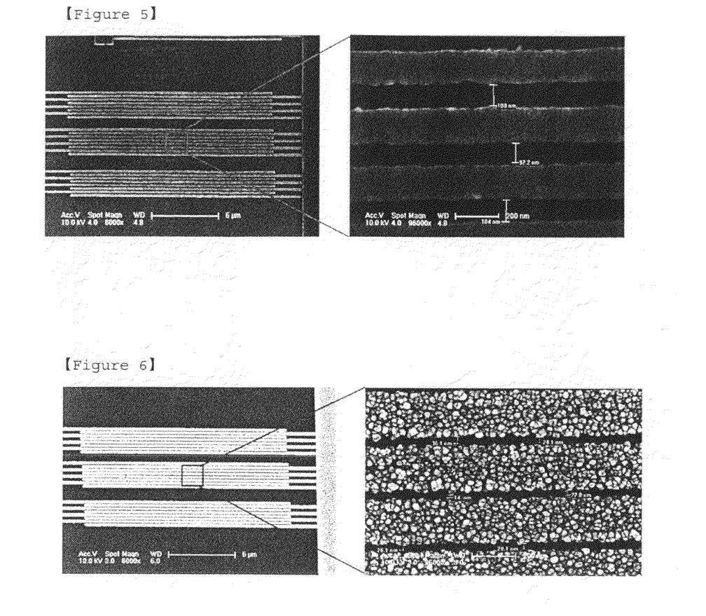

FIG. 5 is a FESEM photograph of a interdigitated gold pattern used in the embodiment 3, and FIG. 6 is a FESEM photograph of interdigitated nanogap gold electrodes formed on the surface of the interdigitated gold pattern. Nanogap electrodes maintaining a uniform width of about 30 nm as illustrated in FIG. 6 was formed after gold was grown on the surface of the gold pattern having a gap distance of about 100 nm as illustrated in FIG. 5.

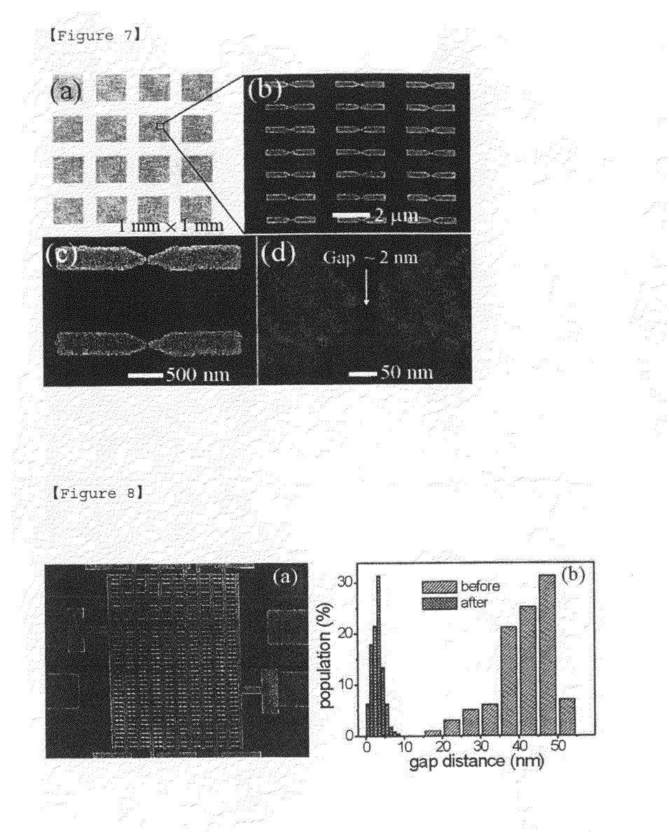

FIG. 7 is a FESEM photograph of 20,000 nanogap electrodes formed within a 1 mm×1 mm area, which is fabricated by a method similar to those of the embodiments, and it is confirmed that these electrodes were prepared with a gap distance of about 2 nm.

FIG. 8(a) is a FESEM photograph of 40×10 nanogap electrodes, and FIG. 8(b) is a histogram of gap distances before or after preparing the nanogap electrodes as illustrated in FIG. 8(a). It is confirmed that the gap having average distance of 42±7.6 nm became narrowed to have average distance of 3.3±1.4 nm. It is also confirmed that very uniform nanogap can be prepared by a method according to the present invention, from the fact that the standard deviation of the gap distance was ±7.6 nm in the case of a metal pattern whereas it was reduced to ±1.4 nm after a metal layer was grown.

### INDUSTRIAL APPLICABILITY

A method of preparing a nanogap electrode according to the present invention has advantages that nanogap electrodes can be easily prepared in a reproducible and uniform manner by controlling the concentration of a reactant and reaction time, and that the interdigitated nanogap electrodes applicable to the field of biosensor or the like can be prepared in an economical manner.

1. A method of preparing a nanogap electrode, wherein reduced metal is grown by reduction reaction from a metal ion in solution on the surface of a metal pattern with a predetermined shape.

2. The method of preparing a nanogap electrode according to claim 1, wherein the metal pattern is formed by any one method selected from electron beam lithography, photo lithography, X-ray lithography, and printing method.

3. The method of preparing a nanogap electrode according to claim 1, wherein the metal pattern and a metal which is grown on the metal pattern are same.

4. The method of preparing a nanogap electrode according to claim 1, wherein the solution contains water or a mixed solvent of water and an organic solvent.

5. The method of preparing a nanogap electrode according to claim 4, wherein the concentration of a metal ion in the solution is 1 μM-1 mM.

6. The method of preparing a nanogap electrode according to claim 1, wherein the gap distance of the formed nanogap electrode is 1-100 nm.

7. The method of preparing a nanogap electrode according to claim 1, wherein the metal pattern is selected from Au, Ag, Al, Cu, and Pt.

8. The method of preparing a nanogap electrode according to claim 1, wherein a substrate formed with a metal pattern having a predetermined shape is immersed in a solution containing a metal ion, and then reduced metal is grown from the metal ion in solution on the surface of the metal pattern by adding a reducing agent to the solution.

9. The method of preparing a nanogap electrode according to claim 8, wherein the metal ion is reduced by adding a reducing agent selected from hydroxylamine (H₂NOH), ascorbic acid, glucose, Rochelle salt, formaldehyde, and their mixture to the solution.

10. The method of preparing a nanogap electrode according to claim 1, wherein the metal ion is selected from HAuCl₄, AgNO₃, AuCl, AuCl₂, AuCl₃, AuCl₄, Au(CO)Cl, NaAuCl₄, and their mixture.

11. A nanogap electrode, wherein the electrode is prepared by a preparing method according to claim 1.

12. The method of preparing a nanogap electrode according to claim 6, wherein a substrate formed with a metal pattern having a predetermined shape is immersed in a solution containing a metal ion, and then reduced metal is grown from the metal ion in solution on the surface of the metal pattern by adding a reducing agent to the solution.

13. The method of preparing a nanogap electrode according to claim 6, wherein the metal ion is selected from HAuCl₄, AgNO₃, AuCl, AuCl₂, AuCl₃, AuCl₄, Au(CO)Cl, NaAuCl₄, and their mixture.
